(19) United States
(12) Patent Application Publication
(10) Pub. No.: US 2014/0357147 A1
(43) Pub. Date: Dec. 4, 2014

(54) CORE OF PRINTED CIRCUIT BOARD AND METHOD OF MANUFACTURING THE SAME

(71) Applicant: SAMSUNG ELECTRO-MECHANICS CO., LTD., Suwon (KR)

(72) Inventors: Tae Hong MIN, Suwon (KR); Sang Hoon KIM, Goonpo (KR); Hye Jin KIM, Yongin (KR)

(73) Assignee: SAMSUNG ELECTRO-MECHANICS CO., LTD., Suwon (KR)

(21) Appl. No.: 14/068,389

(22) Filed: Oct. 31, 2013

(30) Foreign Application Priority Data
May 31, 2013 (KR) 10-2013-0062927

(51) Int. Cl. H05K 1/02; H05K 3/02; H05K 1/03

(52) U.S. Cl. CPC H05K 1/0271; H05K 1/038; H05K 1/0306; H05K 3/022; H05K 2201/09136; H05K 2201/09118; H05K 2203/0736; H05K 2203/0779; H05K 2203/125
USPC 442/169; 442/164; 428/221; 428/426; 428/433; 427/96.1; 65/17.2; 427/97.1; 106/287.34

(57) ABSTRACT

Disclosed herein is a core made of a glass material so as to be capable of preventing generation of warpage in a printed circuit board due to a difference in a coefficient of thermal expansion at the time of manufacturing the printed circuit board. The core includes: an organic cloth; and a glass having the organic cloth formed therein. The core is manufactured in a form in which rigidity thereof is increased by impregnating the organic cloth having a negative coefficient of thermal expansion is impregnated in a liquid-phase glass, thereby making it possible to effectively prevent generation of warpage in the printed circuit board due to the difference in a coefficient of thermal expansion.

### CROSS REFERENCE(S) TO RELATED APPLICATIONS

This application claims the benefit under 35 U.S.C. Section 119 of Korean Patent Application Serial No. 10-2013-0062927, entitled “Core of Printed Circuit Board and Method of Manufacturing the Same” filed on May 31, 2013, which is hereby incorporated by reference in its entirety into this application.

### BACKGROUND OF THE INVENTION

1. Technical Field

The present invention relates to a core of a printed circuit board and a method of manufacturing the same, and more particularly, to a core of a printed circuit board capable of preventing generation of warpage in the printed circuit board due to a difference in a coefficient of thermal expansion at the time of manufacturing the printed circuit board, and a method of manufacturing the same.

2. Description of the Related Art

Generally, a printed circuit board, which is a circuit board serving to electrically connect electronic components to each other or mechanically fix the electronic components, includes an insulating layer made of an insulating material such as phenol resin, an epoxy resin, or the like, and a copper foil layer attached to the insulating layer and having predetermined wiring patterns formed thereon.

The printed circuit board is mainly divided into a single sided PCB in which wiring patterns are formed only on a single surface of the insulating layer, a double sided PCB in which wiring patterns are formed on both surfaces of the insulating layer, and a multi-layer PCB in which a plurality of insulating layers having wiring patterns formed thereon are stacked, such that the wiring patterns are formed as a multi-layer.

Recently, in accordance with miniaturization, thinness, and densification of electronic products, an interest in warpage of a substrate in the multi-layer circuit board has increased.

The warpage of the substrate is mainly generated due to different coefficients of thermal expansion between a core and several stacked insulating layers at the time of manufacturing the multi-layer printed circuit board. In order to minimize the warpage, recently, rigidity of the core has been increased or different coefficients of thermal expansion between the insulating layers stacked at both sides of the core have been applied.

Among them, the core is reinforced with a filler such as glass fiber, silica, or the like, which is a unit for increasing the rigidity of the core, to minimize the warpage of the substrate.

However, in the multi-layer PCB that is being currently manufactured, although the rigidity of the core may be increased to some degree by reinforcing an inner portion of the core with the filler, there is a limitation in overcoming the warpage itself of the substrate, such that there is no large effect.

### RELATED ART DOCUMENT

### Patent Document

(Patent Document 1) Cited Reference: Korean Patent Laid-Open Publication No. 2012-0100408

### SUMMARY OF THE INVENTION

An object of the present invention is to provide a core of a printed circuit board capable of preventing generation of warpage in the printed circuit board due to a difference in a coefficient of thermal expansion by impregnating an organic cloth having a negative coefficient of thermal expansion in a liquid-phase glass to increase rigidity of the core, and a method of manufacturing the same.

Another object of the present invention is to provide a core of a printed circuit board capable of preventing a crack and damage of the core due to brittleness by laminating an insulating material on a surface of the core, and a method of manufacturing the same.

According to an exemplary embodiment of the present invention, there is provided a core of a printed circuit board, including: an organic cloth; and a glass applied to a surface of the organic cloth.

The organic cloth may be any one of P-armid, Toyobo, Zylon, Toraynanoaro, and Kurary LCP having a negative coefficient of thermal expansion.

The glass may have insulating materials laminated on both surfaces thereof and have copper foil layers formed on both surfaces thereof.

The organic cloth may be impregnated in a chemical solution such as epoxy.

According to another exemplary embodiment of the present invention, there is provided a core of a printed circuit board, including: an organic cloth; a glass applied to a surface of the organic cloth; and organic particles present in the glass.

The organic cloth may be any one of P-armid, Toyobo, Zylon, Toraynanoaro, and Kurary LCP having a negative coefficient of thermal expansion.

The glass may have insulating materials laminated on both surfaces thereof and have copper foil layers formed on both surfaces thereof.

The organic cloth may be impregnated in a chemical solution such as epoxy.

According to still another exemplary embodiment of the present invention, there is provided a core of a printed circuit board, including: a glass; and organic particles mixed with the glass. The glass may have insulating materials laminated on both surfaces thereof and have copper foil layers formed on both surfaces thereof.

According to yet still another exemplary embodiment of the present invention, there is provided a method of manufacturing a core of a printed circuit board, including: supplying an organic cloth; impregnating the organic cloth in a chemical solution; applying a liquid-phase glass to a surface of the organic cloth coated with the chemical solution; and cutting the core manufactured by applying the liquid-phase glass.

The core may be adjusted in a thickness while passing through an interval adjusting roller.

According to yet still another exemplary embodiment of the present invention, there is provided a method of manufacturing a core of a printed circuit board, including: preparing organic particles and a chemical solution, respectively; mixing the organic particles and the chemical solution with each other; injecting the organic particles mixed with the chemical solution into a liquid-phase glass; and cutting the core manufactured by injecting the organic particles into the liquid-phase glass according to a standard.

The core may be adjusted in a thickness while passing through an interval adjusting roller.

According to yet still another exemplary embodiment of the present invention, there is provided a method of manufacturing a core of a printed circuit board, including: supplying an organic cloth; preparing organic particles and a chemical coating agent, respectively; mixing the organic particles and the chemical coating agent with each other; impregnating the organic cloth and a result material obtained by the mixing in a chemical solution; applying a liquid-phase glass to surfaces of the impregnated organic cloth and the result material; and cutting the core manufactured by applying the liquid-phase glass.

The core may be adjusted in a thickness while passing through an interval adjusting roller.

### BRIEF DESCRIPTION OF THE DRAWINGS

FIG. 1 is a cross-sectional view showing a cross section of a core of a printed circuit board according to a first exemplary embodiment of the present invention;

FIG. 2 is a view showing a process of manufacturing the core of a printed circuit board of FIG. 1;

FIG. 3 is a cross-sectional view showing a cross section of a core of a printed circuit board according to a second exemplary embodiment of the present invention;

FIG. 4 is a view showing a process of manufacturing the core of a printed circuit board of FIG. 3;

FIG. 5 is a cross-sectional view showing a cross section of a core of a printed circuit board according to a third exemplary embodiment of the present invention;

FIG. 6 is a view showing a process of manufacturing the core of a printed circuit board of FIG. 5; and

FIG. 7 is a graph showing a hardness change of the core depending on a hardness of an organic cloth according to the exemplary embodiment of the present invention.

### DESCRIPTION OF THE PREFERRED EMBODIMENTS

Hereinafter, exemplary embodiments of the present invention will be described in detail with reference to the accompanying drawings.

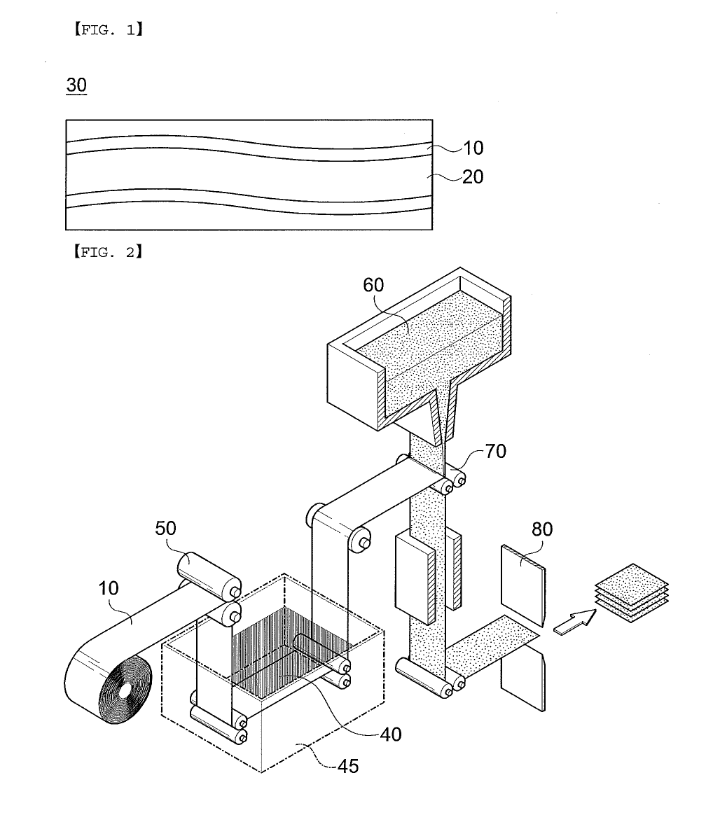

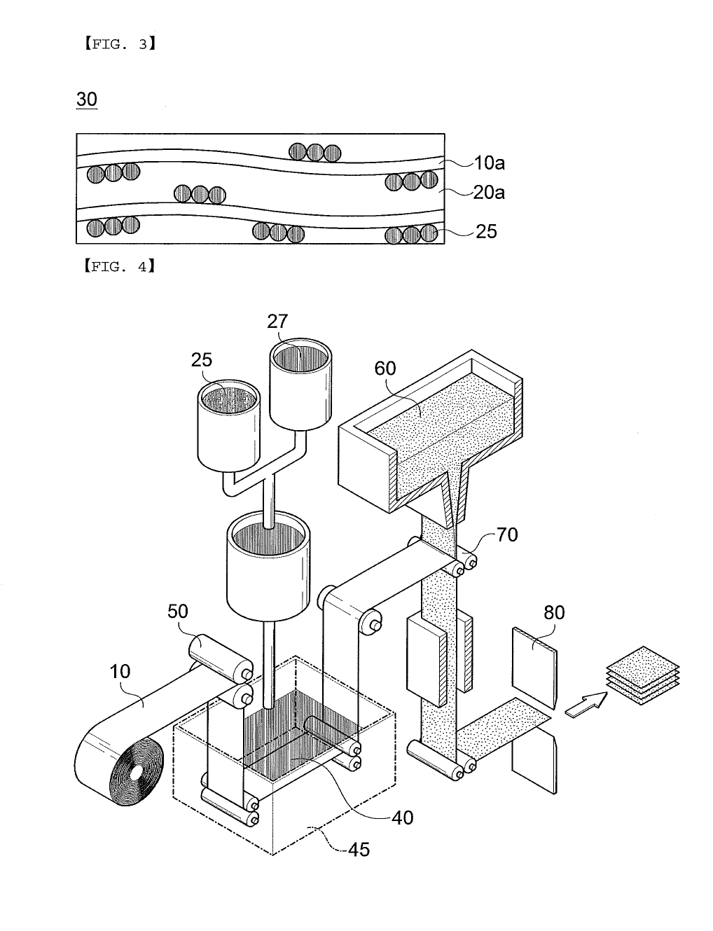

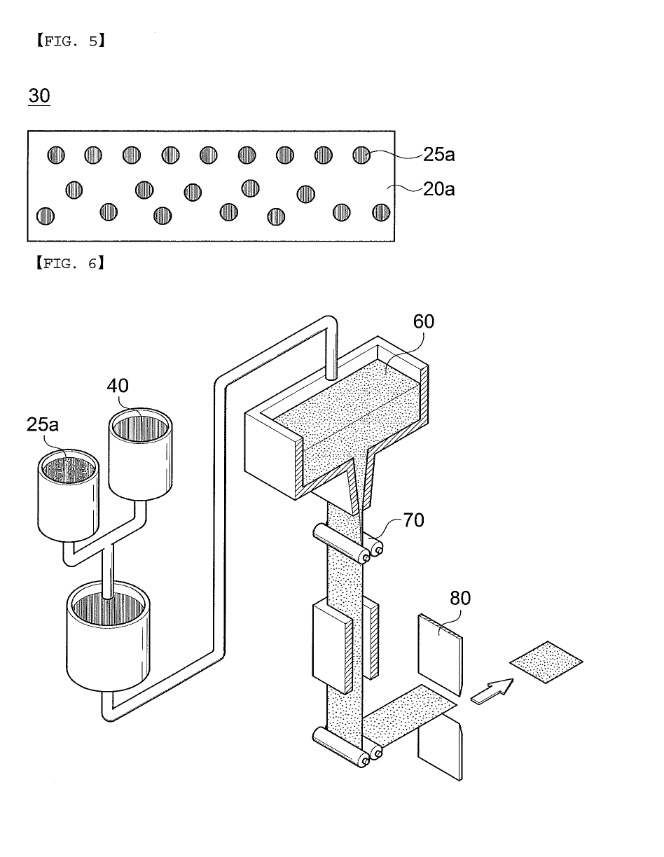

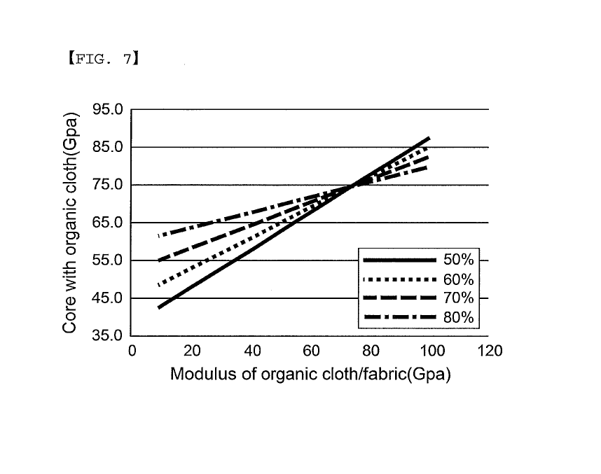

FIG. 1 is a cross-sectional view showing a cross section of a core of a printed circuit board according to a first exemplary embodiment of the present invention; FIG. 2 is a view showing a process of manufacturing the core of a printed circuit board of FIG. 1; FIG. 3 is a cross-sectional view showing a cross section of a core of a printed circuit board according to a second exemplary embodiment of the present invention; FIG. 4 is a view showing a process of manufacturing the core of a printed circuit board of FIG. 3; FIG. 5 is a cross-sectional view showing a cross section of a core of a printed circuit board according to a third exemplary embodiment of the present invention; FIG. 6 is a view showing a process of manufacturing the core of a printed circuit board of FIG. 5; and FIG. 7 is a graph showing a hardness change of the core depending on a hardness of an organic cloth according to the exemplary embodiment of the present invention.

As shown in FIGS. 1 and 2, the core 30 of a printed circuit board according to the first exemplary embodiment of the present invention may be configured to include an organic cloth 10 and a glass 20 having the organic cloth 10 disposed therein.

The organic cloth may be an organic fabric. As the organic cloth 10, a fiber material woven in a lattice shape may be used.

As a material of the organic cloth 10, P-armid, Toyobo, Zylon, Toraynanoaro, Kurary LCP, and the like, among several materials having a negative coefficient of thermal expansion (CTE) may be used. The above-mentioned materials have a modulus of 50 GPa or more.

That is, as the organic cloth 10 according to the exemplary embodiment of the present invention, a material having a negative coefficient of thermal expansion but having a modulus of 50 GPa or more may be used.

The organic cloth 10 is impregnated in and coated with a high temperature chemical solution 40. A material of the chemical solution 40 may be a chemical material having a coating function, such as epoxy. However, the material of the chemical solution 40 is not necessarily limited to the epoxy, but may be any material having the coating function.

The organic cloth 10 is coated with the chemical solution 40 simultaneously with passing through a case 45 in which the chemical solution 40 is filled while being transferred by a roller 50.

After a surface of the organic cloth 10 is coated with the chemical solution 40, the organic solution 40 is air-cooled while being transferred by the roller 50, and a glass solution 60 in a melted state is applied to the surface of the organic cloth 10.

The glass solution 60 may be applied to the surface of the organic cloth 10 by various applying methods such as an upstream method, a downstream method, a floating method, and the like.

The core 30 in a state in which the organic cloth 10 and the glass 20 are integrated with each other by applying the glass solution 60, that is, the core 30 in a state in which the glass solution 60 is applied to the surface of the organic cloth 10 is adjusted in a thickness simultaneously with being air-cooled while passing through an interval adjusting roller 70 and is cut according to a predetermined standard by a cutter 80 before being completely air-cooled.

However, since the core 30 manufactured by the above-mentioned process has an outer surface made of the glass, it has large brittleness, such that it may be cracked or damaged even with small impact.

An insulating material (not shown) such as PPG/ABF may be laminated on a surface of the glass 20 of the core in order to minimize damage to the glass 20 due to impact.

In addition, in the case in which copper foil layers (not shown) are laminated on both surfaces of the glass 20, a function such as a copper clad laminate (CCL) may be implemented.

Meanwhile, FIGS. 3 and 4 show a core of a printed circuit board according to the second exemplary embodiment of the present invention. The core 30 according to the present embodiment may be configured to include an organic cloth 10a, a glass 20a applied to a surface of the organic cloth 10a, and organic particles 25 present in the glass 20a.

As a material of the organic cloth 10a, any one of P-armid, Toyobo, Zylon, Toraynanoaro, and Kurary LCP having a negative coefficient of thermal expansion may be used. The organic cloth 10a is coated with a chemical solution 40 in a process in which it passes through the chemical solution 40 by a roller.

In this case, the organic particles 25 are mixed with a chemical solvent 27 and are then supplied to a case 45 in which the high temperature chemical solution 40 such as epoxy is filled, such that they are impregnated together with the chemical solution 40 in a surface of the organic cloth 10a in a process of coating the organic cloth 10a.

The organic particles 25 may have a size determined depending on a thickness of the core 30, wherein the size may be several nms to several ten nms.

The chemical solvent 27 mixed with the organic particle 25 is to be coated on the surface of the organic particle 25 and serves to protect the organic particle 25 so that the organic particle 25 is not removed or deformed by a high temperature chemical solution 40.

After the organic particles 25 are coated on the surface of the organic cloth 10a as described above, the organic cloth 10a is air-cooled while being transferred by the roller 50, and a glass solution 60 in a melted state is applied to the surface of the organic cloth 10a.

The core 30 having the glass solution 60 applied to the surface of the organic cloth 10a is adjusted in a thickness simultaneously with being air-cooled while passing through an interval adjusting roller 70 and is cut according to a predetermined standard by a cutter 80 before being completely air-cooled.

The core 30 cut by the cutter 80 as described above may have insulating materials laminated on both surfaces thereof in order to supplement brittleness thereof.

In addition, a copper foil layer may be formed on the surface of the glass 20a of the core or on a surface of the laminated insulating material.

FIGS. 5 and 6 show a core of a printed circuit board according to the third exemplary embodiment of the present invention. The core includes a glass 20b and organic particles 25a mixed with the glass 20b.

The core 30 according to the present embodiment is manufactured by the following process. First, organic particles 25a and a chemical solution 40 are prepared, respectively, and the prepared organic particles 25a and the chemical solution 40 are mixed with each other and are injected into a high temperature glass solution 60.

When the organic particles 25a mixed with the organic particles 25a are injected into the glass solution 60, the glass solution 60 is adjusted in a thickness while passing through an interval adjusting roller 70.

The glass solution 60 passing through the interval adjusting roller 70 as described above is slowly air-cooled while being transferred by the roller 50 and is cut by a cutter 80 before being completely air-cooled.

Therefore, in the core 30 manufactured according to the third exemplary embodiment of the present invention, the organic particles 25a having a size of several nms to several ten nms are distributed over an inner portion of the glass 20b. Therefore, the core 30 may have a feature that a crack or damage is not generated in spite of having a large hardness.

In addition, the core 30 may have insulating materials laminated on both surfaces thereof in order to supplement brittleness thereof.

In addition, a copper foil layer may be formed on the surface of the glass 20b of the core or on a surface of the laminated insulating material.

Meanwhile, FIG. 7 shows modulus changes of all the cores depending on a modulus of an organic cloth.

As shown in FIG. 7, it could be appreciated that as the modulus of the organic cloth increases, the moduli of all the cores increase.

Particularly, as a result of representing glass portions by the respective different lines, it could be appreciated that as a glass ratio becomes lower, the moduli of all the cores rapidly increase in accordance with an increase in the modulus of the organic cloth.

In addition, the respective different glass ratios coincide with each other at 75 GPa of all the cores, and the moduli of the organic clothes intersect with each other at 60 to 80 GPa.

When the modulus of the organic cloth increases based on an intersection point, the moduli of all the cores have a gradient opposite to the glass ratio.

In other words, as the glass ratio becomes higher, the modulus of the organic cloth increases, but the moduli of all the cores gradually decrease.

Therefore, it is preferable that the glass ratio is adjusted to be 75 GPa at all the cores and the modulus of the organic cloth is adjusted to be in a range of 60 to 80 GPa.

As described above, when the core having a negative coefficient of thermal expansion but having a modulus of 50 GPa or more is manufactured, even though deformation is generated in the respective built-up insulating layers, rigidity of the core is increased, thereby making it possible to prevent warpage of the printed circuit board.

With the core of a printed circuit board and the method of manufacturing the same according to the exemplary embodiments of the present invention, the organic cloth having the negative coefficient of thermal expansion is impregnated in the liquid-phase glass to manufacture the core of which the rigidity is increased, thereby making it possible to effectively prevent generation of the warpage in the printed circuit board due to a difference in a coefficient of thermal expansion.

In addition, according to the exemplary embodiments of the present invention, the insulating material such as PPG and AFB is laminated on the surface of the core to supplement a disadvantage of the core such as weak brittleness, thereby making it possible to improve salability.

Hereinabove, although the core of a printed circuit board and the method of manufacturing the same according to the exemplary embodiment of the present invention has been described, the present invention is not limited thereto, but may be variously modified and altered by those skilled in the art.

What is claimed is:

1. A core of a printed circuit board, comprising:
an organic cloth; and
a glass applied to a surface of the organic cloth.

2. The core of a printed circuit board according to claim 1, wherein the organic cloth is any one of P-armid, Toyobo, Zylon, Toraynanoaro, and Kurary LCP having a negative coefficient of thermal expansion.

3. The core of a printed circuit board according to claim 1, wherein the glass has insulating materials laminated on both surfaces thereof.

4. The core of a printed circuit board according to claim 1, wherein the glass has copper foil layers formed on both surfaces thereof.

5. The core of a printed circuit board according to claim 1, wherein the organic cloth is impregnated in a chemical solution.

6. A core of a printed circuit board, comprising:
an organic cloth;
a glass applied to a surface of the organic cloth; and
organic particles present in the glass.

7. The core of a printed circuit board according to claim 6, wherein the organic cloth is any one of P-armid, Toyobo, Zylon, Toraynanoaro, and Kurary LCP having a negative coefficient of thermal expansion.

8. The core of a printed circuit board according to claim 6, wherein the glass has insulating materials laminated on both surfaces thereof.

9. The core of a printed circuit board according to claim 6, wherein the glass has copper foil layers formed on both surfaces thereof.

10. The core of a printed circuit board according to claim 6, wherein the organic cloth is impregnated in a chemical solution.

11. A core of a printed circuit board, comprising:
a glass; and
organic particles mixed with the glass.

12. The core of a printed circuit board according to claim 11, wherein the glass has insulating materials laminated on both surfaces thereof.

13. The core of a printed circuit board according to claim 11, wherein the glass has copper foil layers formed on both surfaces thereof.

14. A method of manufacturing a core of a printed circuit board, comprising:
supplying an organic cloth;
impregnating the organic cloth in a chemical solution;
applying a liquid-phase glass to a surface of the organic cloth coated with the chemical solution; and
cutting the core manufactured by applying the liquid-phase glass.

15. The method according to claim 14, wherein the core is adjusted in a thickness while passing through an interval adjusting roller.

16. A method of manufacturing a core of a printed circuit board, comprising:
preparing organic particles and a chemical solution, respectively;
mixing the organic particles and the chemical solution with each other;
injecting the organic particles mixed with the chemical solution into a liquid-phase glass; and
cutting the core manufactured by injecting the organic particles into the liquid-phase glass according to a standard.

17. The method according to claim 16, wherein the core is adjusted in a thickness while passing through an interval adjusting roller.

18. A method of manufacturing a core of a printed circuit board, comprising:
supplying an organic cloth;
preparing organic particles and a chemical coating agent, respectively;
mixing the organic particles and the chemical coating agent with each other;
impregnating the organic cloth and a result material obtained by the mixing in a chemical solution;
applying a liquid-phase glass to surfaces of the impregnated organic cloth and the result material; and
cutting the core manufactured by applying the liquid-phase glass.

19. The method according to claim 18, wherein the core is adjusted in a thickness while passing through an interval adjusting roller.
